(19) United States
(12) Patent Application Publication
(10) Pub. No.: US 2025/0218805 A1
(43) Pub. Date: Jul. 3, 2025

(54) BOWL UNIT AND SUBSTRATE PROCESSING APPARATUS

(71) Applicant: SEMES CO., LTD., Cheonan-si (KR)

(72) Inventors: In Ki JUNG, Hwaseong-si (KR); Jae Youl KIM, Yongin-si (KR); Ho Jong HWANG, Hwaseong-si (KR); Jeong Bo SHIM, Suwon-si (KR); Jeong Hyup YU, Hwaseong-si (KR)

(73) Assignee: SEMES CO., LTD., Cheonan-si (KR)

(21) Appl. No.: 18/999,843

(22) Filed: Dec. 23, 2024

(30) Foreign Application Priority Data
Dec. 27, 2023 (KR) 10-2023-0192572

(51) Int. Cl. H01L 21/67

(52) U.S. Cl. CPC H01L 21/67023

(57) ABSTRACT

Disclosed is an apparatus for processing a substrate, the apparatus including: a substrate support chuck for supporting and rotating a substrate; a nozzle for supplying a treatment liquid to the substrate placed on the substrate support chuck; and a bowl unit configured to surround at least a portion of the substrate support chuck, in which the bowl unit includes: a treatment bowl for providing a liquid recovery path for recovering the treatment liquid and a sub-exhaust path for exhausting airflow around the substrate placed on the substrate support chuck; and an exhaust bowl spaced apart from the treatment bowl, and providing a main exhaust path for exhausting airflow around the substrate placed on the substrate support chuck, the main exhaust path having a greater exhaust flow rate per unit time than the sub-exhaust path.

### CROSS-REFERENCE TO RELATED APPLICATIONS

This application claims priority to and the benefit of Korean Patent Application No. 10-2023-0192572 filed in the Korean Intellectual Property Office on Dec. 27, 2023, the entire contents of which are incorporated herein by reference.

### TECHNICAL FIELD

The present invention relates to a bowl unit and a substrate processing apparatus.

### BACKGROUND ART

To manufacture semiconductor devices, various processes, such as photography, deposition, etching, and ion implantation, are performed on substrates, such as wafers.

Before and after processes, such as photography, deposition, etching, and ion implantation, cleaning processes are performed to clean the substrate. The cleaning process involves applying a cleaning solution to the substrate to clean the substrate. The cleaning process includes a batch type process in which a plurality of substrates are processed by immersing the substrates in a treatment bath, and a single wafer type process in which a single sheet of substrate is supported on a substrate holder, the substrate holder rotates the substrate, and a cleaning solution is supplied to the rotating substrate. This substrate processing method is equally or similarly applicable to a variety of wet treatment processes that processes substrates by applying a treatment liquid to the substrate in addition to the cleaning process.

On the other hand, the chamber for performing the single wafer type process is provided with a bowl unit (also called a cup) for recovering the treatment liquid that is sprayed from the rotating substrate. In order to ensure a more uniform supply of the treatment liquid to the substrate, the airflow around the substrate is exhausted through the bowl unit.

The bowl unit includes a plurality of bowls, and as the plurality of bowls are moved in an up-down direction, the bowl units is formed with a plurality of liquid recovery paths for recovering different types of treatment liquid, and a plurality of exhaust paths. However, when the bowls are moved in the up-down direction to change the liquid recovery paths, the exhaust flow rate of the airflow around the substrate fluctuates significantly while the bowls are moved the an up-down direction. In particular, since the up-and-down movement of the bows is very rapid, the exhaust flow rate fluctuations are very large and abrupt. As described above, the uniformity of the treatment to the substrate is degraded when fluctuations occur in the exhaust flow rate relative to the airflow around the substrate.

### SUMMARY OF THE INVENTION

The present invention has been made in an effort to provide a bowl unit and a substrate processing apparatus capable of effectively processing a substrate.

The present invention has also been made in an effort to provide a bowl unit and a substrate processing apparatus capable of uniformly exhausting airflow around a substrate.

The present invention has also been made in an effort to provide a bowl unit and a substrate processing apparatus capable of effectively recovering and exhausting a treatment liquid supplied to the substrate and fume generated by the supply of the treatment liquid.

The present invention has also been made in an effort to provide a bowl unit and a substrate processing apparatus capable of maintaining a constant exhaust flow rate per unit time for airflow around the substrate, even when bowls are lifted to change a liquid recovery path.

The problem to be solved by the present invention is not limited to the above-mentioned problems, and the problems not mentioned will be clearly understood by those skilled in the art from the descriptions below.

An exemplary embodiment of the present invention provides an apparatus for processing a substrate, the apparatus including: a substrate support chuck for supporting and rotating a substrate; a nozzle for supplying a treatment liquid to the substrate placed on the substrate support chuck; and a bowl unit configured to surround at least a portion of the substrate support chuck, in which the bowl unit includes: a treatment bowl for providing a liquid recovery path for recovering the treatment liquid and a sub-exhaust path for exhausting airflow around the substrate placed on the substrate support chuck; and an exhaust bowl spaced apart from the treatment bowl, and providing a main exhaust path for exhausting airflow around the substrate placed on the substrate support chuck, the main exhaust path having a greater exhaust flow rate per unit time than the sub-exhaust path

According to the exemplary embodiment, the apparatus may further include an exhaust port that communicates with the main exhaust path and the sub-exhaust path, in which the exhaust port may be disposed closer to a rotation axis of the substrate than the exhaust bowl, when viewed from above.

According to the exemplary embodiment, the treatment bowl may include a plurality of bowls configured to be liftable.

According to the exemplary embodiment, the exhaust bowl may be disposed on an outer side of an outer bowl provided at the outermost side among the plurality of bowls.

According to the exemplary embodiment, a space between the exhaust bowl and the outer bowl may define at least a portion of the main exhaust path, at least one of the plurality of bowls may be selectively lifted, and the plurality of bowls may define the plurality of sub-exhaust paths and the plurality of the liquid recovery paths.

According to the exemplary embodiment, a width of the space between the exhaust bowl and the outer bowl may remain constant while at least one of the plurality of bowls is selectively lifted.

According to the exemplary embodiment, the treatment bowl may include the plurality of bowls, and the plurality of bowls may include: the outer bowl; a middle bowl positioned at an inner side compared to the outer bowl; and an inner bowl positioned at an inner side compared to the middle bowl, and the inner bowl and the middle bowl are configured to be liftable.

According to the exemplary embodiment, a space between the exhaust bowl and the outer bowl may define at least a portion of the main exhaust path, a space between the outer bowl and the middle bowl may define at least a portion of a first sub-exhaust path that is one of the sub-exhaust paths, a space between the middle bowl and the inner bowl may define at least a portion of a second sub-exhaust path that is one of the sub-exhaust paths, and an interior space of the inner bowl may define at least a portion of a third sub-exhaust path that is one of the sub-exhaust paths.

According to the exemplary embodiment, the middle bowl may include a first liquid receiving part providing a first drainage recess for recovering the treatment liquid, and the inner bowl may include a second liquid receiving part providing a second drainage recess for receiving the treatment liquid.

According to the exemplary embodiment, the treatment bowl may further include a liquid receiving member including a third liquid receiving part disposed at an inner side of the inner bowl and providing a third drainage recess for recovering the treatment liquid.

According to the exemplary embodiment, the outer bowl may include: a first top portion inclined upwardly in a direction toward the substrate placed on the substrate support chuck; and a first bottom portion providing a first insertion groove into which an outer wall of the first liquid receiving part is inserted, an inner wall of the first insertion groove may be configured vertically in an up and down direction, and the outer wall of the first liquid receiving part may be formed of an inclined surface on a surface facing the inner wall of the first insertion groove.

According to the exemplary embodiment, the middle bowl may include: a second top portion inclined upwardly in a direction toward the substrate placed on the substrate support chuck; and a second bottom portion extending from the second top portion and formed with a first fitting groove into which the first liquid receiving part is fitted, and the first liquid receiving part and the second bottom portion may provide a second insertion groove into which an outer wall of the second liquid receiving part is inserted.

According to the exemplary embodiment, the inner bowl may include: a third top portion inclined upwardly in a direction toward the substrate placed on the substrate support chuck; and a third bottom portion extending from the third top portion and formed with a first fitting groove into which the first liquid receiving part is fitted, and the second liquid receiving part and the third bottom portion may provide a second insertion groove into which an outer portion of the third liquid receiving part is inserted.

According to the exemplary embodiment, the apparatus may further include an exhaust path forming member for defining the main exhaust path and the sub-exhaust path in conjunction with the treatment bowl, in which the exhaust path forming member may include: a first portion extending along a horizontal direction from a lower side of the treatment bowl; and a second portion extending along an up and down direction from an outer side of the exhaust bowl.

According to the exemplary embodiment, the exhaust port may include an inlet that is provided to face a space between the first portion and the treatment bowl so that airflow flowing along a space between the first portion and the treatment bowl is exhausted.

Another exemplary embodiment of the present invention provides a bowl unit including: a treatment bowl providing a liquid recovery path for recovering a treatment liquid supplied to a substrate and a sub-exhaust path for exhausting airflow around the substrate; and a treatment bowl provided at an outer side of the treatment bowl to be spaced apart from the treatment bowl, and providing a main exhaust path for exhausting airflow around the substrate, in which an exhaust flow rate of airflow per unit time exhausted through the main exhaust path is greater than an exhaust flow rate of airflow per unit time exhausted through the sub-exhaust path.

According to the exemplary embodiment, the treatment bowl may include a plurality of liftable bowls, and at least one of the plurality of bowls may be selectively lifted and define the plurality of the sub-exhaust paths and the plurality of the liquid recovery paths, and a space between an outer bowl disposed at the outermost side among the plurality of bowls and the exhaust bowl may define at least a portion of the main exhaust path.

According to the exemplary embodiment, an interval between the exhaust bowl and the outer bowl may remain constant while the plurality of bowls is lifted.

Still another exemplary embodiment of the present invention provides an apparatus for processing a substrate, the apparatus including: a chamber providing an interior space; a substrate support chuck for supporting and rotating a substrate in the interior space; a nozzle for supplying a treatment liquid to the substrate placed on the substrate support chuck; a bowl unit configured to surround at least a portion of the substrate support chuck; and an exhaust unit for exhausting the interior space, in which the bowl unit includes: a treatment bowl providing at least one of a plurality of liquid recovery paths for recovering the treatment liquid and a plurality of sub-exhaust paths for exhausting airflow around the substrate placed on the substrate support chuck; and an exhaust bowl spaced apart from the treatment bowl, and providing a main exhaust path for exhausting airflow around the substrate placed on the substrate support chuck, the main exhaust path having a greater exhaust flow rate per unit time than the plurality of sub-exhaust paths, and the treatment bowl includes: an outer bowl; a middle bowl positioned at an inner side compared to the outer bowl; and an inner bowl positioned at an inner side compared to the middle bowl, and the inner bowl and the middle bowl are configured to be liftable, any one of the plurality of liquid recovery paths and any one of the plurality of sub-exhaust paths are provided as main paths, depending on the lifting of the inner bowl and the middle bowl, the exhaust unit further includes an exhaust port in communication with the main exhaust path and the sub-exhaust path, and the exhaust port is disposed closer to a rotation axis of the substrate than the exhaust bowl, when viewed from above.

According to the exemplary embodiment, the apparatus may further include: a first lifting mechanism for lifting the exhaust bowl; a second lifting mechanism for lifting the outer bowl; a third lifting mechanism for lifting the middle bowl; a fourth lifting mechanism for lifting the inner bowl; and a controller configured to control the first lifting mechanism, the second lifting mechanism, the third lifting mechanism, and the fourth lifting mechanism, the controller may be configured to control the first lifting mechanism, the second lifting mechanism, the third lifting mechanism, and the fourth lifting mechanism to exhaust the airflow around the substrate and recover the treatment liquid in a first mode of providing a first liquid recovery path and a first sub-exhaust path as main paths by positioning the outer bowl in a raised position and the middle bowl and the inner bowl in a lowered position, a second mode of providing a second liquid recovery path and a second sub-exhaust path as the main paths by positioning the outer bowl and the middle in a raised position and the inner bowl in a lowered position, or a third mode of providing a third liquid recovery path and a third sub-exhaust path as the main paths by positioning the outer bowl, the middle bowl, and the inner bowl in a raised position, and during mode switching between the first mode, the second mode, and the third mode, an interval between the outer bowl and the exhaust bowl may remain constant.

According to the exemplary embodiment of the present invention, it is possible to effectively process a substrate.

Further, according to the exemplary embodiment of the present invention, it is possible to uniformly exhaust airflow around a substrate.

Further, according to the exemplary embodiment of the present invention, it is possible to effectively recover and exhaust a treatment liquid supplied to a substrate and fume generated by the supply of the treatment liquid.

Further, according to the exemplary embodiment of the present invention, it is possible to maintain a constant exhaust flow rate per unit time for airflow around the substrate, even when bowls are lifted to change a liquid recovery path.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view of a substrate processing apparatus according to an exemplary embodiment of the present invention.

FIG. 2 is a cross-sectional view illustrating the substrate processing apparatus provided in a process chamber of FIG. 1.

FIG. 3 is an enlarged cross-sectional view for illustrating a bowl unit of FIG. 2 in more detail.

FIG. 4 is a diagram illustrating the bowl unit of FIG. 3 which recovers a liquid and exhausts airflow in a first mode.

FIG. 5 is a diagram illustrating the bowl unit of FIG. 3 which recovers a liquid and exhausts airflow in a second mode.

FIG. 6 is a diagram illustrating the bowl unit of FIG. 3 which recovers a liquid and exhausts airflow in a third mode.

FIG. 7 is experimental data showing an exhaust flow rate of the bowl unit according to the first mode to the third mode.

FIG. 8 is detailed experimental data showing an exhaust flow rate of the bowl unit according to the first mode to the third mode.

FIG. 9 is a graph illustrating a change in exhaust pressure according to a switch of the mode of the bowl unit in an example of the present invention and a comparative example that is a related art.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, a manufacturing method, a substrate processing method, and a substrate processing apparatus according to an exemplary embodiment of the present invention will be described in detail. The manufacturing method may be a method of manufacturing a semiconductor device. The substrate processing method may be processes corresponding to some of various processes required to manufacture the semiconductor device. Further, a substrate processing apparatus may be an apparatus for implementing the above substrate processing method for processing a substrate W, such as a wafer. Further, the substrate processing apparatus may correspond to a semiconductor device manufacturing apparatus capable of performing processes corresponding to some of the various processes required to manufacture the semiconductor devices described above.

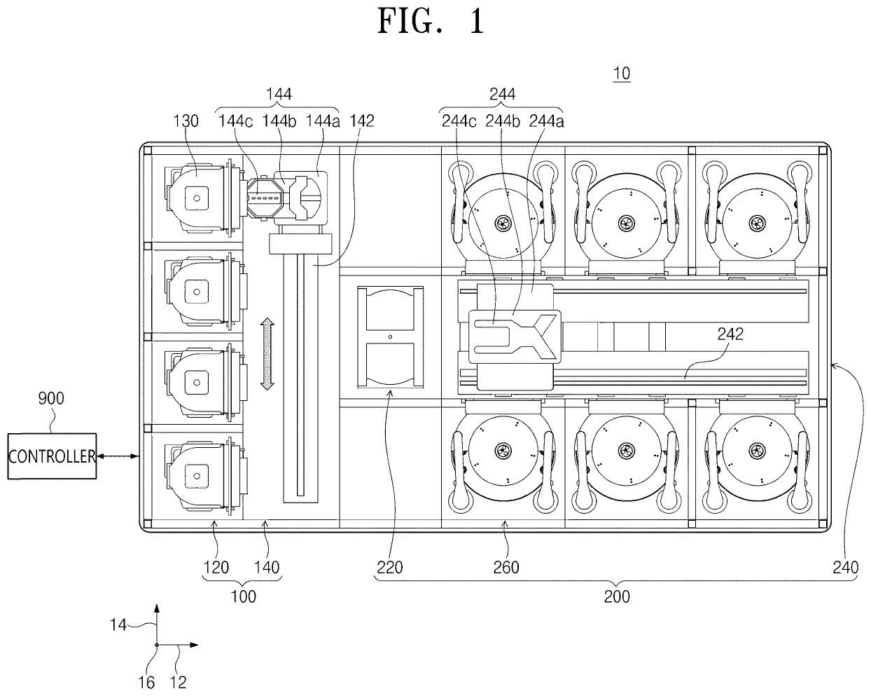

Hereinafter, exemplary embodiments of the present invention will be described in detail with reference to FIGS. 1 to 15.

FIG. 1 is a top plan view of a substrate processing apparatus according to an exemplary embodiment of the present invention.

Referring to FIG. 1, a substrate processing apparatus 10 includes an index module 100, a process processing module 200, and a controller 900. The Index module 100 includes a load port 120 and a transfer frame 140. The load port 120, the transfer frame 140, and the process processing module 20 are arranged in sequential rows. Hereinafter, a direction in which the load port 120, the transfer frame 140, and the process processing module 200 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 130 in which a substrate W is accommodated is seated on the load port 120. A plurality of load ports 120 is provided and is arranged in a line along the second direction 14. The number of load ports 120 may be increased or decreased depending on process efficiency and footprint requirements of the process processing module 200. The carrier 130 is formed with a plurality of slots (not illustrated) for receiving the substrates W in a horizontal position relative to the ground. As the carrier 130, a Front Opening Unified Pod (FOUP) may be used.

The process processing module 200 includes a buffer unit 220, a transfer chamber 240, and a process chamber 260. The transfer chamber 240 may disposed so that a longitudinal direction thereof is parallel to the first direction. The process chambers 260 may be disposed at opposite sides of the transfer chamber 240. On one side of the transfer chamber 240 and on the other side of the transfer chamber 240, the process chambers 260 are provided to be symmetrical with respect to the transfer chamber 240. On one side of the transfer chamber 240, a plurality of process chambers 260 are provided. Some of the process chambers 260 may be disposed in the longitudinal direction of the transfer chamber 240. Further, some of the plurality of process chambers 260 may be disposed to be stacked on each other. That is, the plurality of process chambers 260 may be disposed in an arrangement of A×B at one side of the transfer chamber 240. Here, A is the number of process chambers 260 provided in a line along the first direction 12, and B is the number of process chambers 260 provided in a line along the third direction 16. When four or six process chambers 260 are provided at one side of the transfer chamber 240, the process chambers 260 may be disposed in an arrangement of 2×2 or 3×2. The number of process chambers 260 may be increased or decreased. Unlike the foregoing, the process chamber 260 may be provided only to one side of the transfer chamber 240. In addition, the process chamber 260 may be provided as a single layer on one side and both sides of the transfer chamber 240.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. A slot (not illustrated) in which the substrate W is placed is provided inside the buffer unit 220. A plurality of slots (not illustrated) is provided so as to be spaced apart from each other in the third direction 16. A surface of the buffer unit 220 facing the transfer frame 140 and a surface of the buffer unit 220 facing the transfer chamber 240 may be opened.

The transfer frame 140 transfers the substrate W between the carrier 130 seated at the load port 120 and the buffer unit 220. An index rail 142 and an index robot 144 are provided to the transfer frame 140. A longitudinal direction of the index rail 142 is provided to be parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 130, and another some of the plurality of index arms 144c may be used when the substrate W is transferred from the carrier 130 to the process processing module 200. This may prevent particles generated from the substrate W before the process processing from being attached to the substrate W after the process processing in the process of loading and unloading the substrate W by the index robot 144.

The transfer chamber 2400 transfers the substrate W between the buffer unit 2200 and the process chamber 260, and between the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b. A plurality of main arms 244c is provided to be individually driven. The main arms 244c are disposed to be stacked in the state of being spaced apart from each other in the third direction 16.

The process chamber 260 performs a liquid treatment process on the substrate W. The liquid treatment process may be a cleaning process to clean the substrate W, an etching process to remove a film formed on the substrate W, a developing process to form a pattern by applying a developer to the substrate W, an application process to form a photosensitive film by applying a photosensitizer to the substrate W, or various wet treatment processes that process the substrate W in a single wafer type.

The process chambers 260 may have different structures depending on the type of liquid treatment process being performed. Alternatively, each of the process chambers 260 may have the same structure. Optionally, the process chambers 260 may be divided into a plurality of groups, such that process chambers 260 belonging to the same group may be provided with the same structure, and the process chambers 260 belonging to different groups may be provided with different structures.

The controller 900 may be configured to control the configurations of the substrate processing apparatus 10. The controller 900 may be configured to control the index module 100 and the process processing module 200. Further, the controller 900 may be configured to control the substrate processing apparatus provided in the process chamber 260.

Further, the controller 900 may include a process controller formed of a microprocessor (computer) that executes the control of the substrate processing apparatus 10, a user interface formed of a keyboard in which an operator performs a command input operation or the like in order to manage the substrate processing apparatus 10, a display for visualizing and displaying an operation situation of the substrate processing apparatus 10, and the like, and a storage unit storing a control program for executing the process executed in the substrate processing apparatus 10 under the control of the process controller or a program, that is, a treatment recipe, for executing the process in each component according to various data and processing conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

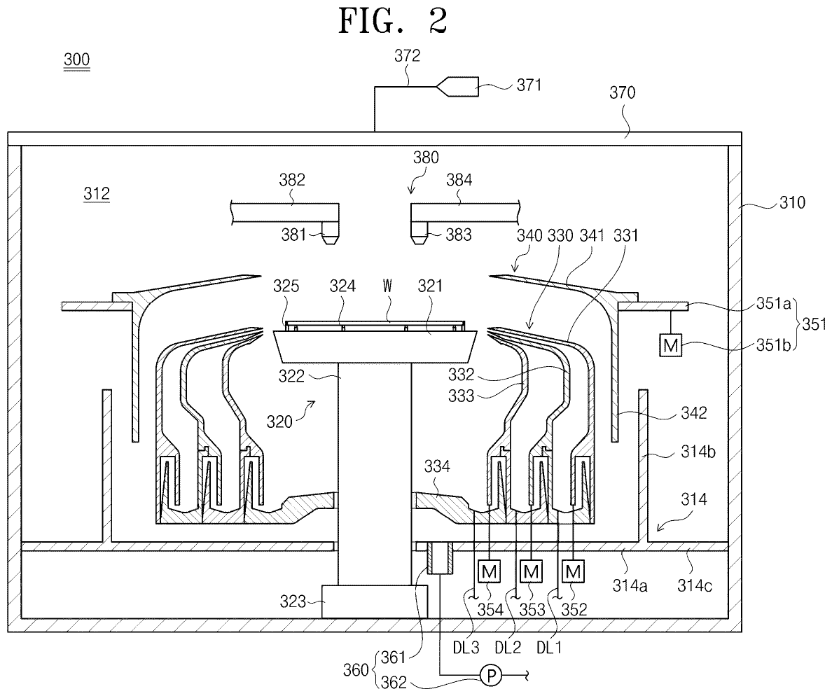

FIG. 2 is a cross-sectional view illustrating the substrate processing apparatus provided in a process chamber of FIG. 1.

Referring to FIG. 2, the substrate processing apparatus 300 provided in the process chamber 260 may include a chamber 310, a substrate support chuck 320, a treatment bowl 330, an exhaust bowl 340, a plurality of lifting mechanisms 351, 352, 353, and 354, an exhaust unit 360, a fan filter unit 370, and a liquid supply unit 380. The configurations of the substrate processing apparatus 300 may be configured to receive control signals from the controller 900 described above to perform operations for processing the substrate W.

The chamber 310 may provide an interior space 312. In the interior space 312, the substrate W may be processed. The chamber 310 may be provided as a barrel-shaped container that may provide the interior space 312. The interior space 312 may be fluidly isolated from the exterior (i.e., the interior space 312 is sealed against the exterior) while a processing process is performed on the substrate W. Alternatively, the interior space 312 may be fluidly connected to the exterior (i.e., at least a portion of the interior space 312 is open to the exterior) even when the processing process is being performed on the substrate W.

At one side of the chamber 310, an opening (not illustrated) may be formed for receiving the substrate W from the transfer chamber 240, or for discharging the substrate W from the transfer chamber 240, and the opening may be optionally shielded by a shielding means, which may be referred to as a shutter, door, or valve, or the like.

Further, the interior space 312 provided by the chamber 310 may be provided with an exhaust path forming member 314. The exhaust path forming member 314 may have the shape of a plate with a circular hole formed in a central region when viewed from above. The exhaust path forming member 314 may be combined with the treatment bowl 330, described later, to define a main exhaust path ME and a sub-exhaust path SE.

The exhaust path forming member 314 may include a first portion 314a extending along a horizontal direction on a downward side of the treatment bowl 330, a second portion 314b extending along an up and down direction on an outward side of the exhaust bowl 340, and a third portion 314c extending along a horizontal direction on an outward side of the second portion 314b. The third portion 314c may be coupled to an inner wall of the chamber 310. All of the first portion 314a to the third portion 314c may be manufactured as a single body, or alternatively, they may be manufactured as separate parts and combined with each other. Further, the exhaust path forming member 314 may be provided with a fixed height, unlike the treatment bowl 330 and the exhaust bowl 340 described later. Further, a rotation shaft 322 of the substrate support chuck 320 described later may be inserted into the hole formed in the center region of the exhaust path forming member 314.

The substrate support chuck 320 may support the substrate W. The substrate support chuck 320 may rotate the substrate W. The substrate support chuck 320 may include a rotation plate 321, a rotation shaft 322, a rotation driver 323, a support pin 324, and a chuck pin 325.

The rotation plate 321 may have a plate shape. The rotation plate 321 may have a disk shape with a wide top surface and a narrow bottom surface. A lower portion of the rotation plate 321 may be connected with the rotation shaft 322. The rotation shaft 322 may rotate the rotation plate 321 to rotate the substrate W supported on the upper side of the rotation plate 321 in a clockwise or counterclockwise direction.

The rotation shaft 322 may be mechanically coupled to the rotation driver 323. The rotational drive force generated by the rotation driver 323 may rotate the rotation shaft 322, and the rotation of the rotation shaft 322 may cause the rotation plate 321 to rotate.

A support pin 324 and a chuck pin 325 may be installed on the rotation plate 321.

The support pins 324 may be provided in a plurality. The plurality of support pins 324 may support the underside of the substrate W at different locations. A plurality of chuck pins 325 may be provided. The plurality of chuck pins 325 may be configured to be laterally movable. Further, the chuck pins 325 may be configured to support the lateral portion and the bottom surface of the edge region of the substrate W together. To this end, the top surface of the chuck pin 325 may have a stepped shape. Further, the chuck pins 325 may be disposed farther from the center of the rotation plate 321 than the support pins 324.

The treatment bowl 330 may recover the treatment liquid supplied by the liquid supply unit 380 described later. The treatment bowl 330 may exhaust airflow around the substrate W. The treatment bowl 330 may provide a liquid recovery path and an airflow exhaust path. The treatment liquid supplied by the liquid supply unit 380 may be recovered through the liquid recovery path, and the airflow around the substrate W may be exhausted to the outside of the substrate processing apparatus 300 through the airflow exhaust path.

The airflow around the substrate W may be airflow supplied by the fan filter unit 370 described later, or may be airflow flowing in a direction toward the substrate W as the atmosphere of the interior space 312 is exhausted through the exhaust unit 360.

The treatment bowl 330 may include a plurality of bowls, such as a first bowl 331 (outer bowl), a second bowl 332 (middle bowl), a third bowl 333 (inner bowl), and a liquid receiving member 334.

The liquid receiving member 334, the third bowl 333, the second bowl 332, and the first bowl 331 may be moved away from the rotation shaft 322 in this order. In other words, the liquid receiving member, the third bowl 333, and the second bowl 332, and the first bowl 331 may be disposed in a direction away from the substrate W in the order of the liquid receiving member, the third bowl 333, and the second bowl 332, and the first bowl 331.

Each of the first bowl 331, the second bowl 332, and the third bowl 333 may be configured to be liftable. Each of the first bowl 331, the second bowl 332, and the third bowl 333 may be configured to be liftable by a second lifting mechanism 352, a third lifting mechanism 353, and a fourth lifting mechanism 354, respectively. The second lifting mechanism 352, the third lifting mechanism 353, and the fourth lifting mechanism 354 may be a motor, a pneumatic/hydraulic cylinder, or the like that is capable of generating lifting drive force to lift the first bowl 331, the second bowl 332, and the third bowl 333.

As the first bowl 331, the second bowl 332, and the third bowl 333 are selectively lifted, a plurality of sub-exhaust paths SE and a plurality of liquid recovery paths LE may be formed. A detailed description of this will be given later.

Further, a first drain line DL1 may be connected to the second bowl 332, a second drain line DL2 may be connected to the third bowl 333, and a third drain line DL3 may be connected to the liquid receiving member 334. The first to third drain lines DL1, DL2, and DL3 may each drain the treatment liquid recovered via the liquid receiving member to the outside of the substrate processing apparatus 300. The first to third drain lines DL1, DL2, and DL3 may recover different types of treatment liquids or, in some cases, may recover the same type of treatment liquids.

The specific construction of the treatment bin 330 will be described later.

The exhaust bowl 340 may be spaced apart and installed on the outer side of the treatment bowl 330. The exhaust bowl 340 may be spaced apart from the outer bowl 331, which is the outermost bowl of the plurality of bowls of the treatment bowl 330. The exhaust bowl 340 may be spaced apart from the outer bowl 331 to define at least a portion of the main exhaust path ME that exhausts airflow around the substrate W placed on the substrate support chuck 320.

The exhaust bowl 340 may be configured to be liftable by the first lifting mechanism 351. The first lifting mechanism 351 may include a ring-shaped lifting bracket 351a that engages the exhaust bowl 340, and a lifting motor 351b that generates lifting drive force to move the lifting bracket 351a in the up and down direction. However, the present invention is not limited thereto, and the first lifting mechanism 351 may also utilize a pneumatic cylinder or hydraulic cylinder in a configuration that generates the lifting drive force.

The specific construction of the exhaust bowl 340 will be discussed later.

The exhaust unit 360 provides decompression to the interior space 312. The exhaust unit 360 provides reduced pressure that allows airflow around the substrate W to be exhausted to the outside of the substrate processing apparatus 300. The exhaust unit 360 may include an exhaust port 361 and an exhaust device 362.

The exhaust port 361 may be connected to a first portion 314a of the exhaust path forming member 314. When viewed from above, the exhaust port 361 may be disposed at a location closer to the rotation shaft 322 than the treatment bowl 330 and the exhaust bowl 340. Further, the inlet of the exhaust port 361 may be configured to exhaust airflow introduced into the exhaust path defined by the space between the treatment bowl 330 and the first portion 314a of the exhaust path forming member 314. The inlet of the exhaust port 361 may be provided to face the space between the exhaust path forming member 314 and the first portion 314a of the exhaust path forming member 314.

The exhaust device 362 may be a device that may provide decompression to the interior space 312 through the exhaust port 361. The exhaust device 362 may be a pump. However, the present invention is not limited thereto, and the exhaust device 3620 may be modified to be any of a variety of devices known in the art that may provide decompression to the interior space 312.

The fan filter unit 370 may provide airflow to the interior space 312. The fan filter unit 370 may supply downdraft airflow into the interior space 312. The downdraft airflow supplied to the interior space 312 may help impurities, such as fume, that may be suspended in the interior space 312 to be exhausted through the exhaust unit 360. The fan filter unit 370 may include a fan to form the downdraft airflow, and a filter to filter particles that may be included in the downdraft airflow entering the interior space 312. Additionally, the fan filter unit 370 may receive a supply of clean dry air (CDA) from an air supply source 371 via an air supply line 372 as needed.

The liquid supply unit 380 may supply the treatment liquid L to the substrate W that is supported and rotated on the substrate support chuck 320.

The liquid supply unit 380 may include a first nozzle 381, a first arm 382, a second nozzle 383, and a second arm 384. The first nozzle 381 is coupled to an end of the first arm 382 and may be changed in position between a process position (where the first nozzle 381 supplies the treatment liquid L to the center of the substrate W) and a standby position (where the first nozzle 381 waits at the top of the standby port). Similarly, the second nozzle 383 is coupled to the end of the second arm 384 and may be changed in position between the process position and the standby position.

The treatment liquid L supplied by the liquid supply unit 380 may be one or more of a cleaning liquid, such as deionized water, isopropyl alcohol, an etchant to remove a film on the substrate W, a developer liquid to develop a film formed on the substrate W and treated with exposure, and a sensitizer liquid, such as a photoresist. The first nozzle 381 and the second nozzle 383 may supply the same type of treatment liquid L, or different types of treatment liquid L may be supplied.

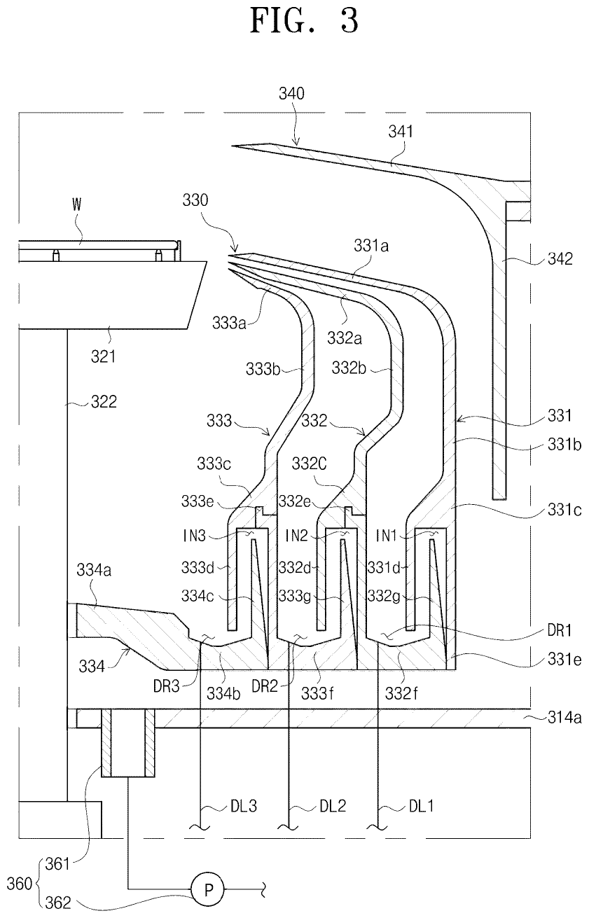

FIG. 3 is an enlarged cross-sectional view for illustrating a bowl unit of FIG. 2 in more detail.

Referring now to FIG. 3, the substrate processing apparatus 300 according to the exemplary embodiment of the present invention may include a treatment bowl 330, and an exhaust bowl 340, as previously described. Herein, the unit formed of the treatment bowl 330 and the exhaust bowl 340 is defined as a bowl unit.

The treatment bowl 330 may include the first bowl 331, the second bowl 332, the third bowl 333, and the liquid receiving member 334. The first bowl 331, the second bowl 332, the third bowl 333, and the liquid receiving member 334 may have a ring-like shape that surrounds the periphery of the substrate support chuck 320.

The first bowl 331 may be an outer bowl. The first bowl 331 may be the outermost disposed bowl of a plurality of bowls that the treatment bowl 330 includes. The first bowl 331 may be formed of a first top portion 331a, a first middle portion 331b, and a first bottom portion 331c. The first top portion 331a, the first middle portion 331b, and the first bottom portion 331c may be manufactured as a single body.

The first top portion 331a may have an upwardly inclined shape in a direction toward the substrate W placed on the substrate support chuck 320. The first top portion 331a may be a portion for preventing the treatment liquid L supplied to the substrate W and scattered from the substrate W from being scattered to the outside of the treatment bowl 330.

The first middle portion 331b may extend in the up and down direction. The first middle portion 331b may extend in the up and down direction, and may be a portion located between the first top portion 331a and the first bottom portion 331c.

The first bottom portion 331c may extend from the first middle portion 331b. The first bottom portion 331c may branch off from the first middle portion 331b to form a first-1 blocking wall 331d and a first-2 blocking wall 331e. The first-2 blocking wall 331e may be disposed at the outer side of the first-1 blocking wall 331d.

The first-1 blocking wall 331d and the first-2 blocking wall 331c may form a first insertion groove IN1. In the first insertion groove IN1, at least a portion of a first liquid receiving part 332f described later may be inserted. For example, an outer wall 332g of the first liquid receiving part 332f may be inserted into the first insertion groove IN.

The second bowl 332 may be a middle bowl. The second bowl 332 may be a bowl disposed between the outermost bowl and the innermost bowl among the plurality of bowls that the treatment bowl 330 includes.

The second bowl 332 may include a second top portion 332a, a second middle portion 332b, and a second bottom portion 332c, and the first liquid receiving part 332f. The second top portion 332a, the second middle portion 332b, and the second bottom portion 332c may be manufactured as a single body. The first liquid receiving part 332f may be manufactured as a separate body from the second top portion 332a, the second middle portion 332b, and the second bottom portion 332c. Manufacturing the second top portion 332a, the second middle portion 332b, and the second bottom portion 332c as a single body and manufacturing the first liquid receiving part 332f as a separate body takes into account ease of setup by an operator when setting up the treatment bowl 330 in the substrate processing apparatus 300.

The second top portion 332a may have an upwardly inclined shape in a direction toward the substrate W placed on the substrate support chuck 320. The second top portion 332a may be a portion for preventing the treatment liquid L supplied to the substrate W and scattered from the substrate W from being scattered to the outside of the treatment bowl 330.

The second middle portion 332b may extend in the up and down direction. The second middle portion 332b may extend in the up and down direction, and may be a portion positioned between the second top portion 332a and the second bottom portion 332c.

The second bottom portion 332c may extend from the second middle portion 332b. The second bottom portion 332c may extend downwardly inclined in a direction toward the rotation shaft 322, and may extend vertically in the up and down direction. The portion extending vertically in the up and down direction may be defined as a second blocking wall 332d. Furthermore, the downwardly inclined portion may have a first fitting groove 332e formed therein. In the first fitting groove 332e, the first liquid receiving part 332f described above may be fitted and fixed by a fixing means, such as a screw/bolt.

The first liquid receiving part 332f may have a generally ring shape when viewed from the top. The first liquid receiving part 332f may define a first drainage recess DR1. The first drainage recess DR1 may be a groove into which the treatment liquid L, which is recovered via the first liquid recovery path LE1 described later, is introduced. The first drainage recess DR1 may be connected to the first drain line DL1.

Further, the outer wall 332g of the first liquid receiving part 332f may be inserted into the first insertion groove IN. The outer wall 334g may include an inclined surface on the surface facing the inner wall of the first insertion groove IN1. For example, the outer wall 334g may include an inclined surface on the side that faces the first-2 blocking wall 331e.

As described above, the first bowl 331 may be lifted in the up and down direction, such that the outer wall 334g is provided with the inclined surface, which may selectively allow or block the flow of airflow through the first sub-exhaust path SE1 formed by the first bowl 331 and the second bowl 332. The first bowl 331 may be lifted in the up and down direction, and the outer wall 334g is provided with the inclined surface, such that when the flow of airflow through the first sub-exhaust path SE1 is blocked, the first liquid receiving part 331e and the first-2 blocking wall 331e are in line contact. This may minimize particle generation due to friction between the first liquid receiving part 331e and the first-2 blocking walls 331e.

The third bowl 333 may be the inner bowl. The third bowl 333 may be the innermost bowl among the plurality of bowls that the treatment bowl 330 includes.

The third bowl 333 may include a third top portion 333a, a third middle portion 333b, and a third bottom portion 333c, and a second liquid receiving part 333f. The third top portion 333a, the third middle portion 333b, and the third bottom portion 333c and the second liquid receiving part 333f may have a generally similar shape and function to the second top portion 332a, the second middle portion 332b, and the second bottom portion 332c and the first liquid receiving part 332f described above, and therefore, repetitive descriptions will be omitted and differences will be emphasized.

The third top portion 333a may be formed to be inclined upwardly in a direction toward the substrate W placed on the substrate support chuck 320, similar to the second top portion 332a, but the inclination angle may be greater than the second top portion 332a, and the length of the third top portion 333a may be shorter than the second top portion 332a.

The second liquid receiving part 333f may be fitted to in a second fitting groove 333e formed in the third bottom portion 333c. The second liquid receiving part 333f may define a second drainage recess DR2, and the second drainage recess DR2 may be connected to the second drain line DL2.

Additionally, the second liquid receiving part 333f may include an outer wall 333g, similar to the first liquid receiving part 332f. The outer wall 333g may be inserted into the second insertion groove IN2, which may be defined by the first liquid receiving part 331f and the second blocking wall 332d. Further, the outer wall 333g may have an inclined surface. The outer wall 333g may be provided with an inclined surface on the surface facing the first liquid receiving part 332f.

The liquid receiving member 334 may include an inner portion 334a, a middle portion 334b, and an outer portion 334c. The top surface of the sinner portion 334a may be provided to be inclined downwardly as being away from the rotation shaft 322. The middle portion 334b and the outer portion 334c may define a third drainage recess DR3. The middle portion 334b and the outer portion 334c may be defined as a third liquid receiving part. The outer portion 334c may be inserted into the third insertion groove IN3 defined by the third blocking wall 333d of the third bowl 333 and the second liquid receiving part 333f. The side of the outer portion 334 facing the second liquid receiving part 333f may be provided with an inclined surface. The third drainage recess DR3 may be connected with the third drain line DL3.

Hereinafter, the first mode to the third mode that are the liquid recovery/airflow exhaust modes providable by the bowl unit of the present invention will be described.

In order for the substrate processing apparatus 300 to implement the first mode to the third mode described below, the controller 900 may generate control signals to control configurations of the substrate processing apparatus 300, such as the first to fourth lifting mechanisms 351, 352, 353, and 354, the exhaust unit 360, the liquid supply unit 380, the fan filter unit 370, the substrate support chuck 320, and the like.

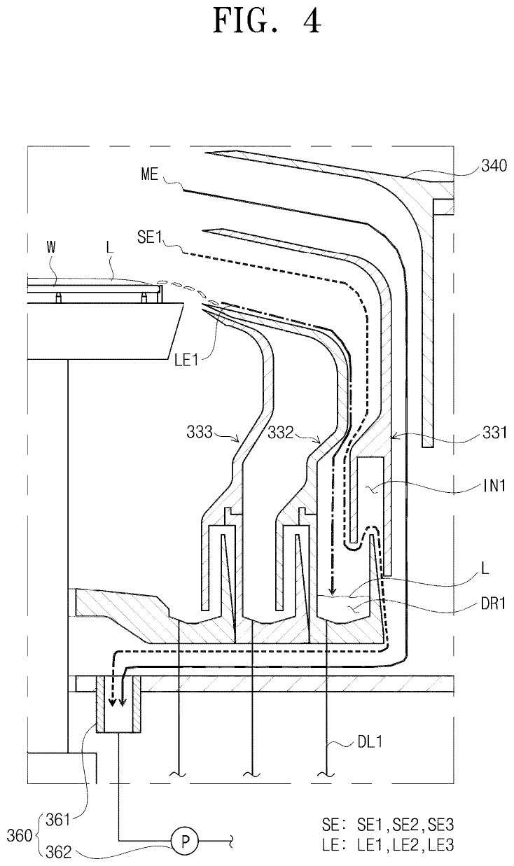

In the following, the arrows illustrating the liquid recovery path LE, the sub-exhaust path SE, and the main exhaust path ME illustrated in FIGS. 4 to 6 are illustrated to illustrate the approximate paths along which the treatment liquid L and airflow are exhausted, and are not meant to imply that the treatment liquid L and airflow necessarily travel only along the paths indicated by the arrows. In other words, the treatment liquid L and airflow travel substantially along the arrows illustrated in FIGS. 4 to 6, but it should be understood that there may be some error in the flow of the treatment liquid L and airflow and the arrows illustrated in FIGS. 4 to 6.

FIG. 4 is a diagram illustrating the bowl unit of FIG. 3 which recovers a liquid and exhausts airflow in the first mode.

Referring to FIG. 4, when the bowl unit recovers the liquid and exhausts the airflow in the first mode, the first bowl 331 may be positioned in a raised position, and the second bowl 332 and the third bowl 333 may be positioned in a lowered position. In the first mode, the first sub-exhaust path SE and the first liquid recovery path LE of the plurality of sub-exhaust paths SE and the plurality of liquid recovery paths LE are provided as the main paths.

When the treatment liquid L is supplied to the substrate W, the treatment liquid L is scattered and recovered along the first liquid recovery path LE1. The treatment liquid L1 recovered along the first liquid recovery path LE1 enters the first drainage recess DR1. The treatment liquid L entering the first drainage recess DR1 may be discharged to the outside of the substrate processing apparatus 300 along the first drain line DL1.

In addition, fumes may be generated by the treatment liquid L during the processing of the substrate W. For example, fumes generated by chemicals contained in the treatment liquid L itself, or fumes generated by films formed on the substrate W or impurities attached to the substrate W reacting with the treatment liquid L need to be exhausted. When the fumes are not exhausted, the fumes may adhere to the components of the substrate processing apparatus 300 and contaminate the substrate W that is subsequently processed.

Such fumes may be exhausted through the first sub-exhaust path SE1, which is defined by the space between the first bowl 331 and the second bowl 332, and the space between the exhaust path forming member 314 and the treatment bowl 330. The first sub-exhaust path SE1 may extend in a downwardly inclined direction along the first top portion 331a and the second top portion 332a, then extend in a downward direction, extend in the up and down direction through the first drainage recess DR1 and the first insertion groove IN1, and move in a horizontal direction toward the exhaust port 361.

Further, the space between the first bowl 331 and the exhaust bowl 340 may define at least a portion of the main exhaust path ME. The main exhaust path ME may be defined by the space between the first bowl 331 and the exhaust bowl 340, and the space between the exhaust path forming member 314 and the treatment bowl 330.

An airflow exhaust flow rate per unit time of the main exhaust path ME may be greater than an airflow exhaust flow rate per unit time of the first sub-exhaust path SE1. This is because the first sub-exhaust path SE1 has more points where the exhaust path changes through the first drainage recess DR1 and the first insertion groove IN than the main exhaust path ME, and the smallest width of the first sub-exhaust path SE1 is smaller than the smallest width of the main exhaust path ME.

In other words, in the first mode, the airflow around the substrate W is mostly exhausted through the main exhaust path ME, the fume is exhausted through the first sub-exhaust path SE1, and the treatment liquid L may be discharged through the first liquid recovery path LE1. Furthermore, since the main exhaust path ME and the first sub-exhaust path SE1 merge near the exhaust port 361, the exhaust efficiency is improved.

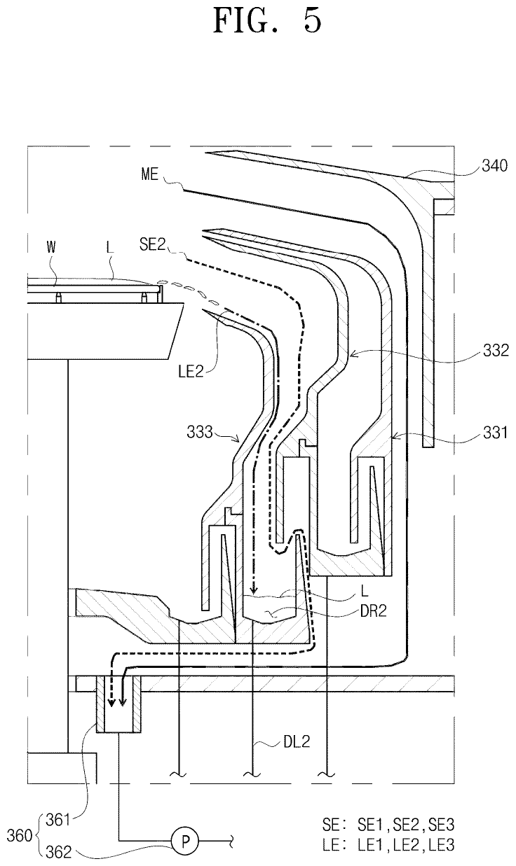

FIG. 5 is a diagram illustrating the bowl unit of FIG. 3 which recovers a liquid and exhausts airflow in the second mode.

Referring to FIG. 5, when the bowl unit recovers the liquid and exhausts airflow in the second mode, the first bowl 331 and the second bowl 332 may be positioned in the raised position and the third bowl 333 may be positioned in the lowered position. In the second mode, the second sub-exhaust path SE2 and the second liquid recovery path LE2 of the plurality of sub-exhaust paths SE and the plurality of liquid recovery paths LE are provided as the main paths.

When the treatment liquid L is supplied to the substrate W, the treatment liquid L is scattered and recovered along the second liquid recovery path LE2. The treatment liquid L1 recovered along the second liquid recovery path LE2 enters the second drainage recess DR2. The treatment liquid L entering the second drainage recess DR1 may be discharged to the outside of the substrate processing apparatus 300 along the second drain line DL2.

In addition, fumes may be generated by the treatment liquid L during the processing of the substrate W. For example, fumes generated by chemicals contained in the treatment liquid L itself, or fumes generated by films formed on the substrate W or impurities attached to the substrate W reacting with the treatment liquid L need to be exhausted. When the fumes are not exhausted, the fumes may adhere to the components of the substrate processing apparatus 300 and contaminate the substrate W that is subsequently processed.

Such fumes may be exhausted through the second sub-exhaust path SE2, which is defined by the space between the second bowl 332 and the third bowl 333, and the space between the exhaust path forming member 314 and the treatment bowl 330. The second sub-exhaust path SE2 may extend in a downwardly inclined direction along the second top portion 332a and the third top portion 333a, then extend in a downward direction, extend in the up and down direction through the second drainage recess DR2 and the second insertion groove IN2, and move in a horizontal direction toward the exhaust port 361.

Further, the space between the second bowl 332 and the exhaust bowl 340 may define at least a portion of the main exhaust path ME. The main exhaust path ME may be defined by the space between the second bowl 332 and the exhaust bowl 340, and the space between the exhaust path forming member 314 and the treatment bowl 330.

An airflow exhaust flow rate per unit time of the main exhaust path ME may be greater than an airflow exhaust flow rate per unit time of the second sub-exhaust path SE2. This is because the second sub-exhaust path SE2 has more points where the exhaust path changes through the second drainage recess DR2 and the second insertion groove IN2 than the main exhaust path ME, and the smallest width of the second sub-exhaust path SE2 is smaller than the smallest width of the main exhaust path ME.

In other words, in the second mode, the airflow around the substrate W is mostly exhausted through the main exhaust path ME, the fume is exhausted through the second sub-exhaust path SE2, and the treatment liquid L may be discharged through the second liquid recovery path LE2. Furthermore, since the main exhaust path ME and the second sub-exhaust path SE2 merge near the exhaust port 361, the exhaust efficiency is improved.

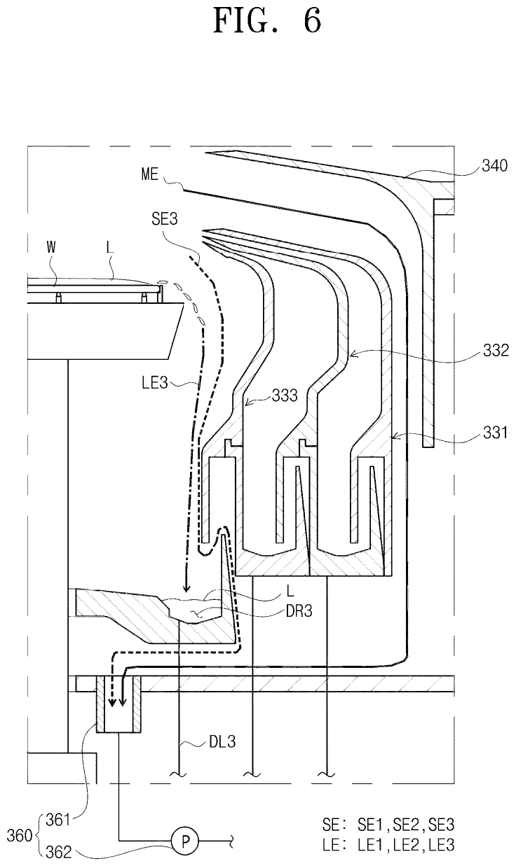

FIG. 6 is a diagram illustrating the bowl unit of FIG. 3 which recovers a liquid and exhausts airflow in a third mode. In the third mode, the third sub-exhaust path SE3 and the third liquid recovery path LE3 of the plurality of sub-exhaust paths SE and the plurality of liquid recovery paths LE are provided as the main paths.

Referring to FIG. 6, when the bowl unit recovers the liquid and exhausts airflow in the third mode, the first bowl 331 and the third bowl 333 may be positioned in the raised position.

When the treatment liquid L is supplied to the substrate W, the treatment liquid L is scattered and recovered along the third liquid recovery path LE3. The treatment liquid L1 recovered along the third liquid recovery path LE3 enters the third drainage recess DR3. The treatment liquid L entering the third drainage recess DR3 may be discharged to the outside of the substrate processing apparatus 300 along the third drain line DL3.

In addition, fumes may be generated by the treatment liquid L during the processing of the substrate W. Such fumes may be exhausted through the third sub-exhaust path SE3, which is defined by the space between the third bowl 333 and the substrate support chuck 320, and the space between the exhaust path forming member 314 and the treatment bowl 330. The third sub-exhaust path SE3 may extend in a downwardly inclined direction along the third top portion 333a, then extend in a downward direction, extend in the up and down direction through the third drainage recess DR3 and the third insertion groove IN3, and move in a horizontal direction toward the exhaust port 361.

Further, the space between the second bowl 332 and the exhaust bowl 340 may define at least a portion of the main exhaust path ME. The main exhaust path ME may be defined by the space between the second bowl 332 and the exhaust bowl 340, and the space between the exhaust path forming member 314 and the treatment bowl 330.

An airflow exhaust flow rate per unit time of the main exhaust path ME may be greater than an airflow exhaust flow rate per unit time of the third sub-exhaust path SE3. This is because the third sub-exhaust path SE3 has more points where the exhaust path changes through the third drainage recess DR3 and the third insertion groove IN3 than the main exhaust path ME, and the smallest width of the third sub-exhaust path SE3 is smaller than the smallest width of the main exhaust path ME.

In other words, in the third mode, the airflow around the substrate W is mostly exhausted through the main exhaust path ME, the fume is exhausted through the third sub-exhaust path SE3, and the treatment liquid L may be discharged through the third liquid recovery path LE3. Furthermore, since the main exhaust path ME and the third sub-exhaust path SE3 merge near the exhaust port 361, the exhaust efficiency is improved.

Furthermore, as may be seen with reference to FIGS. 4 to 6, the interval between the first bowl 331 and the exhaust bowl 340 remains constant. That is, the interval between the first bowl 331 and the exhaust bowl 340 is the same before the mode switch and after the mode switch.

The airflow around the substrate W is mostly exhausted through the main exhaust path ME, which is defined by the space between the first bowl 331 and the exhaust bowl 340. Since most of the airflow is exhausted through the main exhaust path ME, the switching of the sub-exhaust path SE due to the lifting of the first bowl 331, the second bowl 332, and the third bowl 333 makes little difference in the overall exhaust volume exhausted through the exhaust port 361.

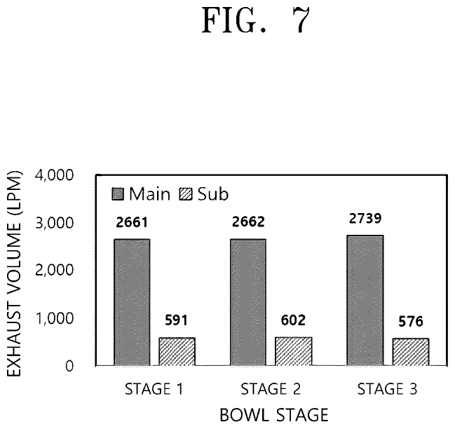

FIG. 7 is experimental data showing an exhaust flow rate of the bowl unit according to the first mode to the third mode. In FIG. 7, stage 1 refers to the first mode, stage 2 refers to the second mode, and stage 3 refers to the third mode. As may be seen from FIG. 7, the exhaust flow rate per unit time exhausted through the main exhaust path ME is not significant even though the mode changes.

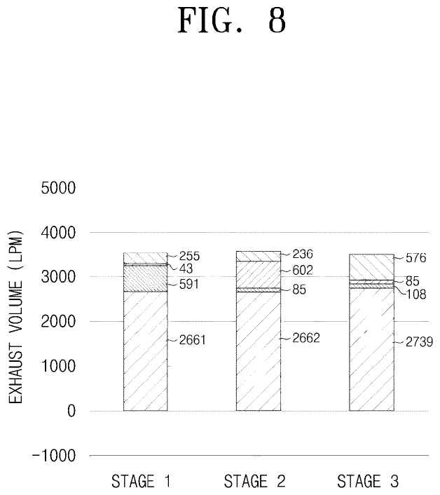

FIG. 7 is detailed experimental data showing an exhaust flow rate of the bowl unit according to the first mode to the third mode. In FIG. 8, stage 1 refers to the first mode, stage 2 refers to the second mode, and stage 3 refers to the third mode.

In the first mode, the airflow exhaust flow rate per unit time exhausted through the main exhaust path ME is 2661 LPM, the airflow exhaust flow rate per unit time exhausted through the first sub-exhaust path SE1 is 591 LPM, the airflow exhaust flow rate per unit time exhausted through the second sub-exhaust path SE2 is 43 LPM, and the airflow exhaust flow rate per unit time exhausted through the third sub-exhaust path SE3 is 255 LPM.

In the second mode, the airflow exhaust flow rate per unit time exhausted through the main exhaust path ME is 2662 LPM, the airflow exhaust flow rate per unit time exhausted through the first sub-exhaust path SE1 is 85 LPM, the airflow exhaust flow rate per unit time exhausted through the second sub-exhaust path SE2 is 602 LPM, and the airflow exhaust flow rate per unit time exhausted through the third sub-exhaust path SE3 is 236 LPM.

In the third mode, the airflow exhaust flow rate per unit time exhausted through the main exhaust path ME is 2739 LPM, the airflow exhaust flow rate per unit time exhausted through the first sub-exhaust path SE1 is 108 LPM, the airflow exhaust flow rate per unit time exhausted through the second sub-exhaust path SE2 is 85 LPM, and the airflow exhaust flow rate per unit time exhausted through the third sub-exhaust path SE3 is 576 LPM.

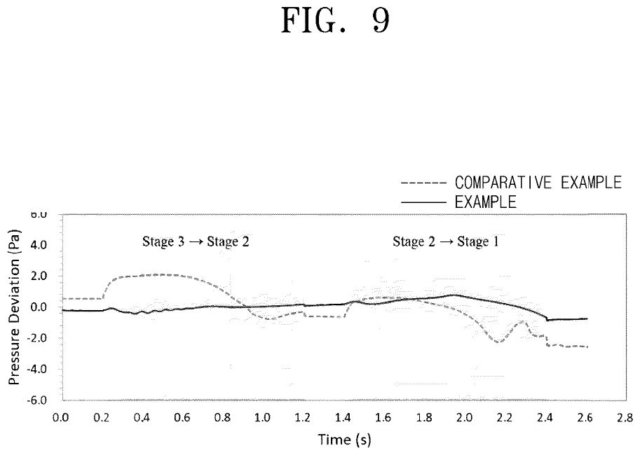

As may be seen in FIGS. 7 and 8, the airflow is mostly exhausted through the main exhaust path ME, and the remainder of the airflow is exhausted through the sub-exhaust paths SE. Therefore, when the bowl unit according to an example of the present invention is used as illustrated in FIG. 9, there is very little hunting of the exhaust pressure. The exhaust pressure in FIG. 9 is measured by a pressure sensor (or pressure gauge) installed in the exhaust line connected with the exhaust port 361, and stage 3 refers to the third mode, stage 2 refers to the second mode, and stage 1 refers to the first mode.

In other words, according to the example of the present invention, as illustrated in FIG. 9, there is almost no pressure hunting phenomenon when switching modes, which means that the airflow around the substrate W may be stably exhausted. By stably exhausting the airflow around the substrate W, the treatment of the substrate W by the treatment liquid L supplied to the substrate W may be carried out uniformly. In addition, the present invention has the advantage of effectively exhausting fume by providing the sub-exhaust path SE, and improving exhaust efficiency by matching the sub-exhaust path SE and the main exhaust path ME near the exhaust port 361.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. An apparatus for processing a substrate, the apparatus comprising:
a substrate support chuck for supporting and rotating a substrate;
a nozzle for supplying a treatment liquid to the substrate placed on the substrate support chuck; and
a bowl unit configured to surround at least a portion of the substrate support chuck,
wherein the bowl unit includes:
a treatment bowl for providing a liquid recovery path for recovering the treatment liquid and a sub-exhaust path for exhausting airflow around the substrate placed on the substrate support chuck; and
an exhaust bowl spaced apart from the treatment bowl, and providing a main exhaust path for exhausting airflow around the substrate placed on the substrate support chuck, the main exhaust path having a greater exhaust flow rate per unit time than the sub-exhaust path.

2. The apparatus of claim 1, further comprising:
an exhaust port that communicates with the main exhaust path and the sub-exhaust path,
wherein the exhaust port is disposed closer to a rotation axis of the substrate than the exhaust bowl, when viewed from above.

3. The apparatus of claim 2, wherein the treatment bowl includes a plurality of bowls configured to be liftable.

4. The apparatus of claim 3, wherein the exhaust bowl is disposed on an outer side of an outer bowl provided at the outermost side among the plurality of bowls.

5. The apparatus of claim 4, wherein a space between the exhaust bowl and the outer bowl defines at least a portion of the main exhaust path,
at least one of the plurality of bowls is selectively lifted, and
the plurality of bowls defines the plurality of sub-exhaust paths and the plurality of the liquid recovery paths.

6. The apparatus of claim 5, wherein a width of the space between the exhaust bowl and the outer bowl remains constant while at least one of the plurality of bowls is selectively lifted.

7. The apparatus of claim 4, wherein the treatment bowl includes the plurality of bowls, and
the plurality of bowls includes:
the outer bowl;
a middle bowl positioned at an inner side compared to the outer bowl; and
an inner bowl positioned at an inner side compared to the middle bowl, and
the inner bowl and the middle bowl are configured to be liftable.

8. The apparatus of claim 7, wherein a space between the exhaust bowl and the outer bowl defines at least a portion of the main exhaust path,
a space between the outer bowl and the middle bowl defines at least a portion of a first sub-exhaust path that is one of the sub-exhaust paths,
a space between the middle bowl and the inner bowl defines at least a portion of a second sub-exhaust path that is one of the sub-exhaust paths, and
an interior space of the inner bowl defines at least a portion of a third sub-exhaust path that is one of the sub-exhaust paths.

9. The apparatus of claim 8, wherein the middle bowl includes a first liquid receiving part providing a first drainage recess for recovering the treatment liquid, and
the inner bowl includes a second liquid receiving part providing a second drainage recess for receiving the treatment liquid.

10. The apparatus of claim 9, wherein the treatment bowl further includes a liquid receiving member including a third liquid receiving part disposed at an inner side of the inner bowl and providing a third drainage recess for recovering the treatment liquid.

11. The apparatus of claim 10, wherein the outer bowl includes:
a first top portion inclined upwardly in a direction toward the substrate placed on the substrate support chuck; and
a first bottom portion providing a first insertion groove into which an outer wall of the first liquid receiving part is inserted,
an inner wall of the first insertion groove is configured vertically in an up and down direction, and
the outer wall of the first liquid receiving part is formed of an inclined surface on a surface facing the inner wall of the first insertion groove.

12. The apparatus of claim 11, wherein the middle bowl includes:
a second top portion inclined upwardly in a direction toward the substrate placed on the substrate support chuck; and
a second bottom portion extending from the second top portion and formed with a first fitting groove into which the first liquid receiving part is fitted, and
the first liquid receiving part and the second bottom portion provide a second insertion groove into which an outer wall of the second liquid receiving part is inserted.

13. The apparatus of claim 12, wherein the inner bowl includes:
a third top portion inclined upwardly in a direction toward the substrate placed on the substrate support chuck; and
a third bottom portion extending from the third top portion and formed with a first fitting groove into which the first liquid receiving part is fitted, and
the second liquid receiving part and the third bottom portion provide a second insertion groove into which an outer portion of the third liquid receiving part is inserted.

14. The apparatus of claim 2, further comprising:
an exhaust path forming member for defining the main exhaust path and the sub-exhaust path in conjunction with the treatment bowl, and
wherein the exhaust path forming member includes:
a first portion extending along a horizontal direction from a lower side of the treatment bowl; and
a second portion extending along an up and down direction from an outer side of the exhaust bowl.

15. The apparatus of claim 14, wherein the exhaust port includes an inlet that is provided to face a space between the first portion and the treatment bowl so that airflow flowing along a space between the first portion and the treatment bowl is exhausted.

16. A bowl unit comprising:
a treatment bowl providing a liquid recovery path for recovering a treatment liquid supplied to a substrate and a sub-exhaust path for exhausting airflow around the substrate; and
a treatment bowl provided at an outer side of the treatment bowl to be spaced apart from the treatment bowl, and providing a main exhaust path for exhausting airflow around the substrate,
wherein an exhaust flow rate of airflow per unit time exhausted through the main exhaust path is greater than an exhaust flow rate of airflow per unit time exhausted through the sub-exhaust path.

17. The bowl unit of claim 14, wherein the treatment bowl includes a plurality of liftable bowls, and
at least one of the plurality of bowls is selectively lifted and defines the plurality of the sub-exhaust paths and the plurality of the liquid recovery paths, and
a space between an outer bowl disposed at the outermost side among the plurality of bowls and the exhaust bowl defines at least a portion of the main exhaust path.

18. The bowl unit of claim 17, wherein an interval between the exhaust bowl and the outer bowl remains constant while the plurality of bowls is lifted.

19. An apparatus for processing a substrate, the apparatus comprising:
a chamber providing an interior space;
a substrate support chuck for supporting and rotating a substrate in the interior space;
a nozzle for supplying a treatment liquid to the substrate placed on the substrate support chuck;
a bowl unit configured to surround at least a portion of the substrate support chuck; and
an exhaust unit for exhausting the interior space,
wherein the bowl unit includes:
a treatment bowl providing at least one of a plurality of liquid recovery paths for recovering the treatment liquid and a plurality of sub-exhaust paths for exhausting airflow around the substrate placed on the substrate support chuck; and
an exhaust bowl spaced apart from the treatment bowl, and providing a main exhaust path for exhausting airflow around the substrate placed on the substrate support chuck, the main exhaust path having a greater exhaust flow rate per unit time than the plurality of sub-exhaust paths, and
the treatment bowl includes:
an outer bowl;
a middle bowl positioned at an inner side compared to the outer bowl; and
an inner bowl positioned at an inner side compared to the middle bowl, and
the inner bowl and the middle bowl are configured to be liftable,
any one of the plurality of liquid recovery paths and any one of the plurality of sub-exhaust paths are provided as main paths, depending on the lifting of the inner bowl and the middle bowl,
the exhaust unit further includes an exhaust port in communication with the main exhaust path and the sub-exhaust path, and
the exhaust port is disposed closer to a rotation axis of the substrate than the exhaust bowl, when viewed from above.

20. The apparatus of claim 19, further comprising:
a first lifting mechanism for lifting the exhaust bowl;
a second lifting mechanism for lifting the outer bowl;
a third lifting mechanism for lifting the middle bowl;
a fourth lifting mechanism for lifting the inner bowl; and
a controller configured to control the first lifting mechanism, the second lifting mechanism, the third lifting mechanism, and the fourth lifting mechanism,
the controller is configured to control the first lifting mechanism, the second lifting mechanism, the third lifting mechanism, and the fourth lifting mechanism to exhaust the airflow around the substrate and recover the treatment liquid in a first mode of providing a first liquid recovery path and a first sub-exhaust path as main paths by positioning the outer bowl in a raised position and the middle bowl and the inner bowl in a lowered position, a second mode of providing a second liquid recovery path and a second sub-exhaust path as the main paths by positioning the outer bowl and the middle in a raised position and the inner bowl in a lowered position, or a third mode of providing a third liquid recovery path and a third sub-exhaust path as the main paths by positioning the outer bowl, the middle bowl, and the inner bowl in a raised position, and
during mode switching between the first mode, the second mode, and the third mode, an interval between the outer bowl and the exhaust bowl remains constant.
